(19) United States
(12) Patent Application Publication
(10) Pub. No.: US 2022/0350942 A1
(43) Pub. Date: Nov. 3, 2022

(54) DISPLAY DEVICE, DISPLAY METHOD, AND DISPLAY PROGRAM

(71) Applicant: NTT Communications Corporation, Tokyo (JP)

(72) Inventors: Daichi KIMURA, Saitama-shi (JP); Tomomi OKAWACHI, Tokyo (JP)

(73) Assignee: NTT Communications Corporation, Tokyo (JP)

(21) Appl. No.: 17/863,413

(22) Filed: Jul. 13, 2022

Related U.S. Application Data
(63) Continuation of application No. PCT/JP2020/047397, filed on Dec. 18, 2020.

(30) Foreign Application Priority Data
Jan. 14, 2020 (JP) 2020-003969

(51) Int. Cl. G06F 30/18

(52) U.S. Cl. CPC G06F 30/18

(57) ABSTRACT

A display device includes processing circuitry configured to acquire data of a plurality of pieces of equipment that are set in a facility, store, in a storage, a correspondence relationship between the respective pieces of equipment that are set in the facility and respective components in drawing data in which the pieces of equipment arranged in the facility are drawn as the components, and on receiving designation of a specific component among the components in the drawing data, choose a specific piece of equipment corresponding to the specific component using the correspondence relationship that is stored in the storage and display data of the specific piece of equipment and data of an equipment group having a causal connection with the specific piece of equipment in association with each other.

### CROSS-REFERENCE TO RELATED APPLICATIONS

This application is a continuation application of International Application No. PCT/JP2020/047397 filed on Dec. 18, 2020 which claims the benefit of priority of the prior Japanese Patent Application No. 2020-003969, filed on Jan. 14, 2020, the entire contents of which are incorporated herein by reference.

### FIELD

The present disclosure relates to a display device, a display method, and a display program.

### BACKGROUND

In various process industries of chemicals, steels, energies, etc., piping and instrumentation diagrams (P&ID) have been widely used as what representing a flow in a plant, control information, and a correspondence relationship of main facilities, such as sensors. A P&ID is requested to design a plant and makes it possible to visualize a correspondence relationship between devices and make a flow easy to understand.

Based on the P&ID, a driver monitors the state in the plant in real time and performs maintenance and operation. The P&ID forms a base of a live model view that is displayed on a graphical user interface of a large-scaled industrial control system, such as a SCADA (Supervisory Control And Data Acquisition) or a distributed control system.

Non Patent Document 1: “Piping and instrumentation diagram”, [online], [searched 6 January, 2020], Internet <en.wikipedia.org/wiki/Piping and instrumentation diagram>.

With the related method, however, it is not possible to visualize sensor data and dependency between sensors in a form that is easy for users to understand. In other words, because enormous numbers of facilities and sets of control equipment are present in the plant, it is practically difficult for the driver to perform monitoring by sight and operations while understanding all sensor data on the P&ID.

### SUMMARY

It is an object of the present invention to at least partially solve the problems in the related technology.

According to an aspect of the embodiments, a display device includes: processing circuitry configured to: acquire data of a plurality of pieces of equipment that are set in a facility; store, in a storage, a correspondence relationship between the respective pieces of equipment that are set in the facility and respective components in drawing data in which the pieces of equipment arranged in the facility are drawn as the components; and on receiving designation of a specific component among the components in the drawing data, choose a specific piece of equipment corresponding to the specific component using the correspondence relationship that is stored in the storage and display data of the specific piece of equipment and data of an equipment group having a causal connection with the specific piece of equipment in association with each other.

The above and other objects, features, advantages and technical and industrial significance of this invention will be better understood by reading the following detailed description of presently preferred embodiments of the invention, when considered in connection with the accompanying drawings.

### BRIEF DESCRIPTION OF DRAWINGS

FIG. 1 is a diagram of a configuration of a system including a display device according to a first embodiment;

FIG. 2 is a block diagram illustrating an example of the configuration of the display device according to the first embodiment;

FIG. 3 is a diagram illustrating an example of data that is stored in a sensor data storage unit;

FIG. 4 is a diagram illustrating an example of data that is stored in a drawing data storage unit;

FIG. 5 is a diagram illustrating an example of data that is stored in an associated data storage unit;

FIG. 6 is a diagram illustrating an example of a screen display that is displayed by the display device;

FIG. 7 is a flowchart illustrating an example of a flow of a display process in the display device according to the first embodiment; and

FIG. 8 is a diagram illustrating a computer that executes a display program.

### DESCRIPTION OF EMBODIMENT(S)

Preferred embodiments will be explained with reference to accompanying drawings. An embodiment of a display device, a display method, and a display program according to the present application will be described in detail below with reference to the accompanying drawings. Note that the embodiment does not limit the display device, the display method and the display program according to the present application.

### First Embodiment

As for the following embodiment, an example of a configuration of a system including a display device 10 according to a first embodiment, an example of a configuration of the display device 10, and a flow of a process performed by the display device 10 will be described sequentially and an effect enabled by the first embodiment will be described last.

Configuration of System

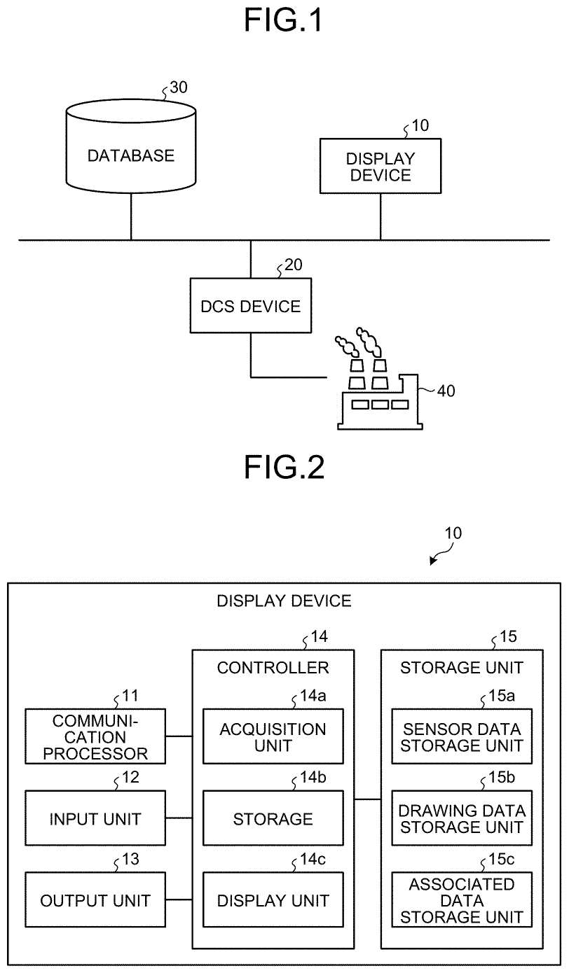

First of all, using FIG. 1, the configuration of the system including the display device 10 will be described. FIG. 1 is a diagram of the configuration of the system including the display device according to the first embodiment. The system exemplified in FIG. 1 includes a DCS (Distributed Control System) device 20, a database 30, and a facility 40. The configuration illustrated in FIG. 1 is an example only and the specific configuration and the number of devices are not particularly limited.

The display device 10 is, for example, a terminal device, such as a work station, that acquires information of the database 30 and displays flow information on a process, real-time sensor information, etc., based on a P&ID on a GUI (Graphical User Interface) application.

The DCS device 20 collects information from equipment in the facility 40 (for example, control equipment and sensors) and stores the collected information in the database 30. Control devices of the respective pieces of equipment communicate with each other and monitor each other and accordingly the DCS device 20 controls each piece of equipment in the facility 40.

The database 30 stores information on the equipment in the facility 40. For example, the database 30 stores various types of sensor data in the facility 40. The facility 40 is a factory, a plant, or the like, and equipment, such as sensors and control equipment, is set in the facility 40.

Configuration of Display Device

Using FIG. 2, the configuration of the display device 10 will be described next. FIG. 2 is a block diagram illustrating an example of the configuration of the display device according to the first embodiment. As illustrated in FIG. 1, the display device 10 includes a communication processor 11, an input unit 12, an output unit 13, a controller 14 and a storage unit 15. Processes performed by the respective units that the display device 10 includes will be described below.

The communication processor 11 performs data communication with another device via a network. For example, the communication processor 11 is a NIC (Network Interface Card). The input unit 12 receives an input of data from a user. The input unit 12 is, for example, an input device, such as a mouse or a keyboard. The output unit 13 outputs data by making a display on a screen, or the like. The output unit 13 is, for example, a display device, such as a display.

The storage unit 15 stores data and programs requested for various processes enabled by the controller 14 and includes a sensor data storage unit 15a, a drawing data storage unit 15b, and an associated data storage unit 15c. For example, the storage unit 15 is a storage device, such as a semiconductor memory device like a RAM (Random Access Memory) or a flash memory.

The sensor data storage unit 15a stores sensor data that is acquired by an acquisition unit 14a to be described below from the database 30. For example, the sensor data storage unit 15a stores values of various types of sensor data in association with sensor IDs that identify the sensors.

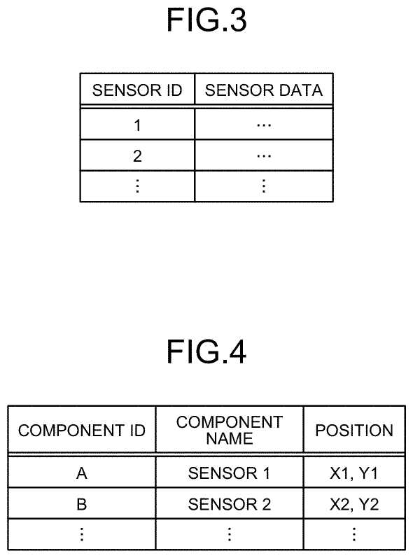

Using the example in FIG. 3, an example of the data that is stored in the sensor data storage unit 15a will be described. FIG. 3 is a diagram illustrating an example of data that is stored in the sensor data storage unit. As exemplified in FIG. 3, the sensor data storage unit 15a stores a “sensor ID” and “sensor data” in association with each other. The sensor data storage unit 15a stores, as the sensor data, values of various types of sensor data, such as an acceleration (three axes), a luminance, a humidity, a magnetic force, and a pressure, and times at which the sets of sensor data are acquired.

The drawing data storage unit 15b stores drawing data in which the equipment arranged in the facility 40 is drawn as components. For example, the drawing data storage unit 15b stores data of a piping and instrumentation diagram, such as a P&ID. The drawing data storage unit 15b stores data of the components that are contained in the drawing data.

Using the example in FIG. 4, an example of the data that is stored in the drawing data storage unit 15b will be described here. FIG. 4 is a diagram illustrating an example of the data that is stored in the drawing data storage unit. As exemplified in FIG. 4, the drawing data storage unit 15b stores a “component ID” that identifies a component, a “component name” that is the name of the component, and a “position” that represents the coordinates of the component on the drawing in association with one another. The drawing data that is stored in the drawing data storage unit 15b is sored previously.

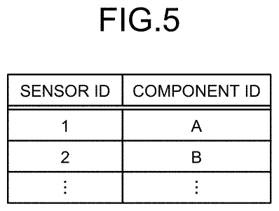

The associated data storage unit 15c stores data representing a correspondence relationship between respective pieces of equipment that are set in the facility 40 and the components in the drawing data. Using the example in FIG. 5, an example of the data that is stored in the associated data storage unit 15c will be described here. FIG. 5 is a diagram illustrating an example of the data that is stored in the associated data storage unit. As exemplified in FIG. 5, the associated data storage unit 15c stores a “sensor ID” and a “component ID” in association with each other. For example, in the example in FIG. 5, the associated data storage unit 15c stores a sensor ID “1” and a component ID “A”. This means that the sensor of the sensor ID “1” is the component of the component ID “A” on the drawing data.

The controller 14 includes an internal memory for storing programs that define various process procedures, etc., and requested data and executes various processes according to the programs and data. For example, the controller 14 includes the acquisition unit 14a, a storage 14b, and a display unit 14c. The controller 14 is, for example, an electronic circuit, such as a CPU (Central Processing Unit), a MPU (Micro Processing Unit) or a GPU (Graphical Processing Unit), or an integrated circuit, such as an ASIC (Application Specific Integrated Circuit) or a FPGA (Field Programmable Gate Array).

The acquisition unit 14a acquires data of a plurality of pieces of equipment that are set in the facility 40 and the drawing data in which the pieces of equipment arranged in the facility 40 are drawn as components. For example, the acquisition unit 14a acquires data of a plurality of sensors that are set in the facility 40, such as a factory or a plant, from the database 30 and stores the sensor data in the sensor data storage unit 15a.

The sensor data that the acquisition unit 14a acquires is, for example, various types of data, such as a temperature, a pressure, a sound, vibrations, etc., on devices and a reactor in a factory or a plant that is the facility to be monitored. The acquisition unit 14a may acquire data in real time. For example, the acquisition unit 14a may regularly (for example, every minute) acquire multivariate time series numerical data from the sensors that are set in the facility to be monitored, such as a factory or a plant.

The storage 14b stores, in the associated data storage unit 15c, the correspondence relationship between the respective pieces of equipment that are set in the facility 40 and the respective components in the drawing data in which the pieces of equipment that are set in the facility 40 are drawn as the components.

For example, the storage 14b specifies to which of the components stored in the drawing data storage unit 15b each of the sensors stored in the sensor data storage unit 15a corresponds and stores an ID of the sensor and its corresponding component ID in association with each other in the associated data storage unit 15c. The method of performing the specifying may be any method and, for example, the storage 14b may perform the specifying automatically using a component name or a tag that is contained in the drawing data or the specifying may be performed manually.

A process of automatically associating each sensor and each component will be described, taking a specific example. The storage 14b, for example, acquires the sensor ID of each sensor from the sensor data storage unit 15a, searches the drawing data storage unit 15b for the same component name or a similar component name as or to the sensor ID, and specifies a component whose component name is the same as or similar to the sensor ID as a component corresponding to the sensor of the sensor ID.

On receiving designation of a specific component among the components in the drawing data, the display unit 14c chooses a specific piece of equipment corresponding to the specific component using the correspondence relationship that is stored in the associated data storage unit 15c. The display unit 14c displays the data of the specific piece of equipment and data of an equipment group having a causal connection with the specific piece of equipment in association with each other.

For example, the display unit 14c acquires, from the sensor data storage unit 15a, sensor data of a sensor group having causal connection with sensor data of a specific sensor from the sensor data storage unit 15a, acquires data of a P&ID from the drawing data storage unit 15b, generates image data containing the P&ID and the sensor data using the acquired data, and displays the generated image data. Note that the display unit 14c may cause another device to display the generated image data.

The display unit 14c may display a directed graph corresponding to a relationship between the data of the specific piece of equipment and the data of the equipment group having the causal connection with the specific piece of equipment. For example, the display unit 14c arranges an arc (directed edge of the graph) between corresponding nodes according to the causal connection that is determined between sets of univariate time-series data. The causal connection may be calculated in any way and, for example, the causal connection is calculated based on a statistic, such as a cross correlation between data of the specific sensor and other sensor data, and a machine learning method, such as LiNGAM.

The display unit 14c arranges an arc when, for example, the maximum value of an absolute value of the cross correlation exceeds a certain threshold. The display unit 14c may determine an orientation of the arc, for example, according to whether the value of a lag is positive or negative at the time when the absolute value of the cross correlation is at maximum. For example, the display unit 14c may determine a color of the arc according to a sign of the value of the cross correlation at the time when the absolute value of the cross correlation is at maximum.

The display unit 14c may group the data of the specific piece of equipment and the data of the equipment group having the causal connection with the specific piece of equipment and display the grouped data. As described above, with respect to sensor data focused on, the display unit 14c presents an appropriate causal connection by a directed graph based on a statistic, such as a cross correlation between sets of data, and a machine learning method, such as LiNGAM, or provides a grouping function, thereby making it possible to easily acquire information that a user needs.

The display unit 14c may specify a piece of equipment on which a user focuses, using logs of operations performed by the user, and further display the piece of equipment on which the user focuses. For example, the display unit 14c may provide a function of suggesting sensor data on which the user often focuses, using machine learning from the logs of operations performed by the user. Accordingly, the display unit 14c is able to recommend sensor data that the user often sees from the logs of operations.

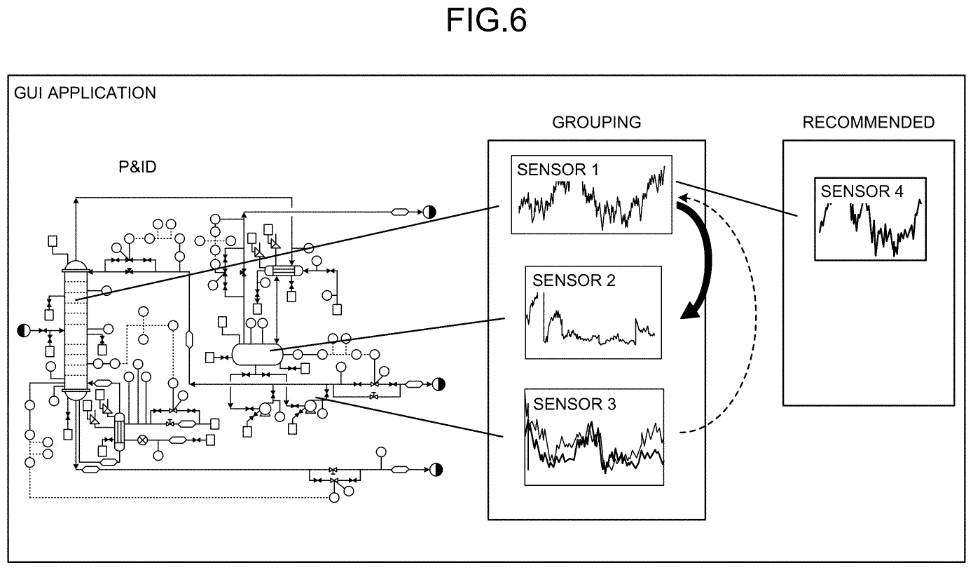

Using FIG. 6, an example of a screen display that is displayed by the display device 10 will be described here. FIG. 6 is a diagram illustrating the example of the screen display that is displayed by the display device. As exemplified in FIG. 6, the display device 10 displays the data of the P&ID on a GUI application. The display device 10 receives designation of a specific component in the P&ID and groups sensor data of the sensor 1 corresponding to the specific component and sets of sensor data of a sensor 2 and a sensor 3 having a causal connection with the sensor 1 and displays the grouped sensor data.

The display device 10 generates a directed graph based on a causal connection that is calculated according to the statistic and machine learning and displays the intensity of dependency by a thickness or color of a line. The display device 10 displays sensor data of a sensor 4 that the user often sees as a recommendation from logs of operations performed by the user.

Process Procedure taken by Display Device

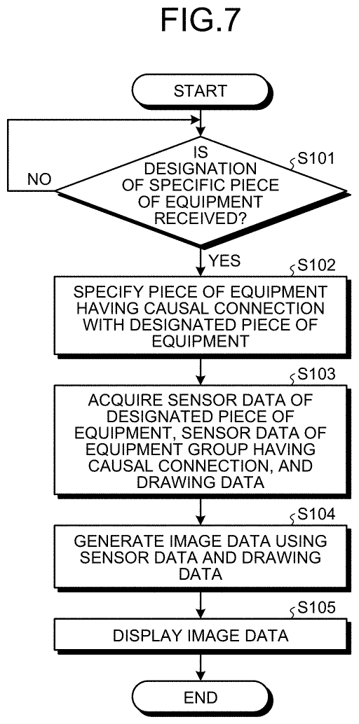

Using FIG. 7, an example of the process procedure taken by the display device 10 according to the first embodiment will be described next. FIG. 7 is a flowchart illustrating an example of a flow of a learning process in the display device according to the first embodiment.

As exemplified in FIG. 7, on receiving designation of a specific piece of equipment on the P&ID (YES at step S101), the display unit 14c of the display device 10 specifies a piece of equipment having a causal connection with the designated piece of equipment (step S102).

The display unit 14c acquires sensor data of the designated piece of equipment, sensor data of a sensor group having the causal connection, and drawing data (step S103). Specifically, the display unit 14c acquires the sensor data of a specific sensor and sensor data of a sensor group having a causal connection from the sensor data storage unit 15a and acquires the data of the P&ID from the drawing data storage unit 15b.

Subsequently, using the sensor data and the drawing data that are acquired, the display unit 14c generates image data (step S104) and displays the image data (step S105). For example, the display unit 14c generates image data containing the P&ID and the sensor data, arranges an arc (directed edge of a graph) between corresponding nodes according to the causal connection that is determined between sets of univariate time-series data, and groups the data of the specific piece of equipment and the data of the equipment group having the causal connection with the specific piece of equipment and displays the grouped data. The display unit 14c may specify a piece of equipment on which a user focuses, using logs of operations performed by the user, and further display the piece of equipment on which the user focuses.

### Effect of First Embodiment

The display device 10 according to the first embodiment acquires data of a plurality of pieces of equipment that are set in the facility 40 and stores, in the associated data storage unit 15c, a correspondence relationship between the respective pieces of equipment that are set in the facility 40 and respective components in drawing data in which the pieces of equipment that are set in the facility 40 are drawn as the components. On receiving designation of a specific component among the components in the drawing data, the display device 10 chooses a specific piece of equipment corresponding to the specific component using the correspondence relationship that is stored in the associated data storage unit 15c and displays data of the specific piece of equipment and data of an equipment group having a causal connection with the specific piece of equipment in association with each other. Therefore, the display device 10 is able to visualize sensor data and dependency between sensors in a form that is easy for users to understand. For example, when an abnormality occurs in the facility 40 in the display device 10, collectively visualizing not only the site of abnormality but also corresponding parts enables understanding of a cause and a range of effect and speedy maintenance support.

The display device 10 arranges an arc when the maximum value of an absolute value of a cross correlation exceeds the certain threshold. The display device 10 groups the data of the specific piece of equipment and the data of the equipment group having the causal connection with the specific piece of equipment and displays the grouped data. As described above, with respect to sensor data focused on, the display device 10 presents an appropriate causal connection by a directed graph or provides a grouping function, thereby making it possible to easily acquire information that a user needs.

The display device 10 may specify a piece of equipment on which the user focuses, using logs of operations performed by the user, and further display the piece of equipment on which the user focuses. For example, the display unit 14c may provide a function of suggesting sensor data on which the user often focuses, using machine learning from the logs of operations performed by the user. Accordingly, the display device 10 is able to recommend sensor data that the user often sees from the logs of operations.

System Configuration, Etc.

Each component of each device illustrated in the drawings is a functional idea and need not necessarily be configured physically as illustrated in the drawings. In other words, specific modes of distribution and integration of devices are not limited to those illustrated in the drawings, and all or part of the devices can be configured by functional or physical distribution or integration in any unit according to various types of load and usage. Furthermore, all or given part of each processing function implemented by each device can be implemented by a CPU or a GPU and a program that is analyzed and executed by the CPU or the GPU or can be implemented as hardware according to a wired logic.

Among the processes described in the above-described embodiment, all or part of the process that is described as one performed automatically can be performed manually or all or part of the process that has been described as one performed manually can be performed automatically by a known method. In addition to this, the process procedure, control procedure, specific names, and information including various types of data and parameters that are presented in the above description and the drawings are changeable freely unless otherwise noted.

Program

It is possible to create a program in which the process executed by the information processing device described in the above-described embodiment is written in a computer-executable language. For example, it is also possible to create a program in which the process executed by the display device 10 according to the embodiment is written in a computer-executable language. In this case, execution of the program by a computer enables the same effect as that of the above-described embodiment. Furthermore, the program may be recorded in a computer-readable recording medium and a computer may be caused to read and execute the program that is recorded in the recording medium, thereby implementing the same process as that of the above-described embodiment.

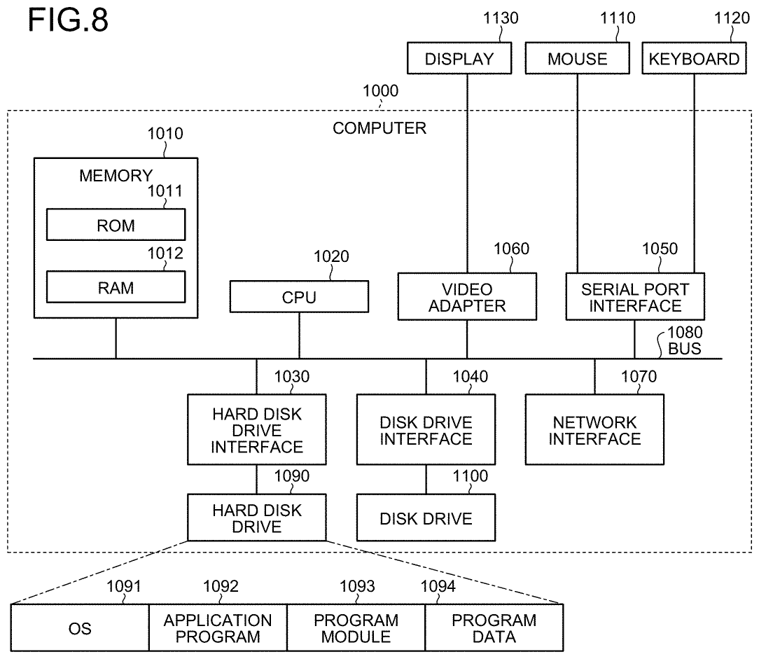

FIG. 8 is a diagram illustrating a computer that executes a display program. As exemplified in FIG. 8, a computer 1000 includes, for example, a memory 1010, a CPU 1020, a hard disk drive interface 1030, a disk drive interface 1040, a serial port interface 1050, a video adapter 1060, and a network interface 1070 that are connected via a bus 1080.

As exemplified in FIG. 8, the memory 1010 includes a ROM (Read Only Memory) 1011 and a RAM 1012. The ROM 1011 stores, for example, a boot program, such as a BIOS (Basic Input Output System). As exemplified in FIG. 8, the hard disk drive interface 1030 is connected to a hard disk drive 1090. As exemplified in FIG. 8, the disk drive interface 1040 is connected to a disk drive 1100. For example, a detachable recording medium, such as a magnetic disk or an optical disk, is inserted into the disk drive 1100. As exemplified in FIG. 8, the serial port interface 1050 is connected to, for example, a mouse 1110 and a keyboard 1120. As exemplified in FIG. 8, the video adapter 1060 is connected to, for example, a display 1130.

As exemplified in FIG. 8, the hard disk drive 1090 stores, for example, an OS 1091, an application program 1092, a program module 1093, and program data 1094. In other words, the above-described program is stored in, for example, the hard disk drive 1090 as a program module in which instructions that are executed by the computer 1000 are written.

The various types of data described in the above-described embodiment are stored as program data in, for example, the memory 1010 or the hard disk drive 1090. The CPU 1020 reads the program module 1093 and the program data 1094 that are stored in the memory 1010 or the hard disk drive 1090 into the RAM 1012 as requested and executes the various process procedures.

The program module 1093 and the program data 1094 according to the program are not limited to being stored in the hard disk drive 1090, and the program module 1093 and the program data 1094 may be stored in a detachable storage medium and may be read by the CPU 1020 via a disk drive, or the like. Alternatively, the program module 1093 and the program data 1094 according to the program may be stored in another computer that is connected via a network (such as a LAN (Local Area Network) or a WAN (Wide Area Network)) and may be read by the CPU 1020 via the network interface 1070.

According to the disclosure, an effect that it is possible to visualize sensor data and dependency between sensors in a form that is easy for users to understand is enabled.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A display device comprising:
processing circuitry configured to:
acquire data of a plurality of pieces of equipment that are set in a facility;
store, in a storage, a correspondence relationship between the respective pieces of equipment that are set in the facility and respective components in drawing data in which the pieces of equipment arranged in the facility are drawn as the components; and
on receiving designation of a specific component among the components in the drawing data, choose a specific piece of equipment corresponding to the specific component using the correspondence relationship that is stored in the storage and display data of the specific piece of equipment and data of an equipment group having a causal connection with the specific piece of equipment in association with each other.

2. The display device according to claim 1, wherein the processing circuitry is further configured to display a directed graph corresponding to a relationship between the data of the specific piece of equipment and the data of the equipment group having the causal connection with the specific piece of equipment.

3. The display device according to claim 1, wherein the processing circuitry is further configured to group the data of the specific piece of equipment and the data of the equipment group having the causal connection with the specific piece of equipment and display the grouped data.

4. The display device according to claim 1, wherein the processing circuitry is further configured to specify a piece of equipment on which a user focuses, using logs of operations performed by the user, and further display the piece of equipment on which the user focuses.

5. A display method comprising:
acquiring data of a plurality of pieces of equipment that are set in a facility;
storing, in a storage, a correspondence relationship between the respective pieces of equipment that are set in the facility and respective components in drawing data in which the pieces of equipment arranged in the facility are drawn as the components; and
on receiving designation of a specific component among the components in the drawing data, choosing a specific piece of equipment corresponding to the specific component using the correspondence relationship that is stored in the storage and displaying data of the specific piece of equipment and data of an equipment group having a causal connection with the specific piece of equipment in association with each other, by processing circuitry.

6. A non-transitory computer-readable recording medium storing therein a display program that causes a computer to execute a process comprising:
acquiring data of a plurality of pieces of equipment that are set in a facility;
storing, in a storage, a correspondence relationship between the respective pieces of equipment that are set in the facility and respective components in drawing data in which the pieces of equipment arranged in the facility are drawn as the components; and
on receiving designation of a specific component among the components in the drawing data, choosing a specific piece of equipment corresponding to the specific component using the correspondence relationship that is stored in the storage and displaying data of the specific piece of equipment and data of an equipment group having a causal connection with the specific piece of equipment in association with each other.
